(19) United States
(12) Patent Application Publication
(10) Pub. No.: US 2025/0077721 A1
(43) Pub. Date: Mar. 6, 2025

(54) SYSTEM AND METHOD FOR CAPTURE OF PHYSICAL OBJECT DATA FOR ENVIRONMENT MODELING

(71) Applicant: XEROX CORPORATION, NORWALK, CT (US)

(72) Inventors: Lester D. Nelson, Santa Clara, CA (US); Eric A. Bier, Palo Alto, CA (US); Alejandro E. Brito, Mountain View, CA (US)

(21) Appl. No.: 18/459,206

(22) Filed: Aug. 31, 2023

(51) Int. Cl. G06F 30/13; G06T 17/20; G06T 19/00

(52) U.S. Cl. CPC G06F 30/13; G06T 17/20; G06T 19/00; G06F 3/013; G06F 3/017; G06F 3/167; G06T 2210/04; G06T 2219/004

(57) ABSTRACT

A system and method for captures of physical object data for environment modeling is provided. Mesh data is displayed over an image of a physical space for which a floorplan is to be generated. Instructions to mark an object are received and the instructions include a voice command and eye gaze or gesture. The mesh data is annotated with a marker based on the instructions by placing the marker at a location at which an object is to be identified. A floorplan of the space is generated based on the mesh data. The marker is placed in the floorplan.

### FIELD

This application relates in general to 3D modeling and in particular to a system and method for capture of physical object data for environment modeling.

### BACKGROUND

Floorplans of a desired space are useful for navigating in a building, planning furniture placement, planning a remodel, planning the placement of pipes, wires, ducts, sensors and thermostats, and modeling the building for heating, ventilation, and air conditioning (HVAC) applications. For example, the building sector accounts for a considerable portion of energy usage and sensors or other devices can be placed within a building to monitor and control such energy uses.

However, producing a floorplan can be a time-consuming and expensive process that requires expert skills, including the measuring of distances and angles, and entering data into a CAD program, for example. Furthermore, this process may need to be performed more than once because the floorplan of a building can change over a period of time, such as when walls are moved, added, or removed, for example.

Automatic floorplan generation reduces the time and expense conventionally needed to generate a floorplan and can include gathering triangle mesh data. The mesh data is then converted into a floorplan by identifying and rotating floors and walls, and placing representations of physical objects in the floorplan. Automatically generating floorplans is further discussed in U.S. patent application Ser. No. 18/297,506, to Bier et al., which is hereby incorporated by reference in its entirety. While generating floorplans automatically greatly reduces time and cost, physical objects placed in a space for which a floorplan is generated may not be recognizable via the triangle mesh data and can be improperly identified. For example, a sensor with a box like shape may be attached to a wall or ceiling; however, even if the mesh triangles accurately represent the sensor, no identification of the sensor is provided by the mesh triangle data.

Accordingly, a system and method for capturing and annotating physical environments is needed. Object annotations improve modeling techniques for spaces, including accurately identifying and labeling objects within the space. Preferably, physical objects are marked in an environment and metadata is assigned to the object anchored in spatial data.

### SUMMARY

Automatic floor plan generation should be able to be used by anyone capable of moving around in a building and looking at its walls, floors, and ceilings and require little or no training. A resulting automatic floorplan can show walls, chairs, tables, file cabinets, and other furniture and is automatically aligned with horizontal and vertical axes. If desired, a user can annotate the positions of sensors, thermostats, vents, doors, windows, and other objects and these will appear in the floorplan as well. A first style of floorplan can resemble a pen-and-ink diagram that shows features at different distances from the floor, and a second style of floorplan resembles a drafting diagram. Clutter in the space represented by the floor plan can be removed by recognizing walls in 3D space before projection to 2D. The resulting floorplan can include the positions of sensors, thermostats, vents, doors, windows, and other objects.

Annotations of the objects can occur via one or more of trace marking, voice commands, gaze pointing, and gesture.

An embodiment provides a system and method for capture of physical object data for environment modeling. Mesh data is displayed over an image of a physical space for which a floorplan is to be generated. Instructions to mark an object are received and the instructions include a voice command and eye gaze or gesture. The mesh data is annotated with a marker based on the instructions by placing the marker at a location at which an object is to be identified. A floorplan of the space is generated based on the mesh data. The marker is placed in the floorplan.

Still other embodiments will become readily apparent to those skilled in the art from the following detailed description, wherein are described embodiments by way of illustrating the best mode contemplated. As will be realized, other and different embodiments are possible and the embodiments' several details are capable of modifications in various obvious respects, all without departing from their spirit and the scope. Accordingly, the drawings and detailed description are to be regarded as illustrative in nature and not as restrictive.

### BRIEF DESCRIPTION OF THE DRAWINGS

FIG. 1 is a block diagram showing a system for capture of physical object data for environment modeling, in accordance with one embodiment.

FIG. 2 is a flow diagram showing, by way of example, a method for automatic floorplan generation.

FIG. 3 is a block diagram showing, by way of example, a space for which mesh triangles are gathered via an augmented reality headset.

FIG. 4 is a block diagram showing, by way of example, a portion of a space with a sensor object.

FIG. 5 is a block diagram showing, by way of example, a model of a space with a floor that is not initially level.

FIG. 6 is an image showing, by way of example, trace marking used on an object.

FIG. 7 is a screenshot 100 of an image of a space with mesh triangles showing, by way of example, a marker for a corner.

FIG. 8 is a screenshot of an image of a physical space with mesh triangles and normal lines.

FIG. 9 is a flow diagram showing, by way of example, interaction 80 of different features of an application for object annotation.

### DETAILED DESCRIPTION

Currently, obtaining a floorplan takes time and money due to requiring expert skill and the arduous task of measuring distances and angles within a space for which the floorplan is generated. Some floorplans can take days or longer to generate. To obtain floorplans at a lower cost and in a lesser amount of time, automatic floorplan generation can be utilized by obtaining triangle mesh data for a space and converting the triangle mesh data into a representation of the space. However, accurately capturing and identifying objects placed within the space can be difficult. For instance, a thermostat or sensor placed on a wall appears box like and can be represented by the mesh data. However, a representation of the box like shape, without any further information, is difficult to label or identify. Accordingly, object annotations, in addition to the triangle mesh data, can be used to identify and accurately label objects within the space.

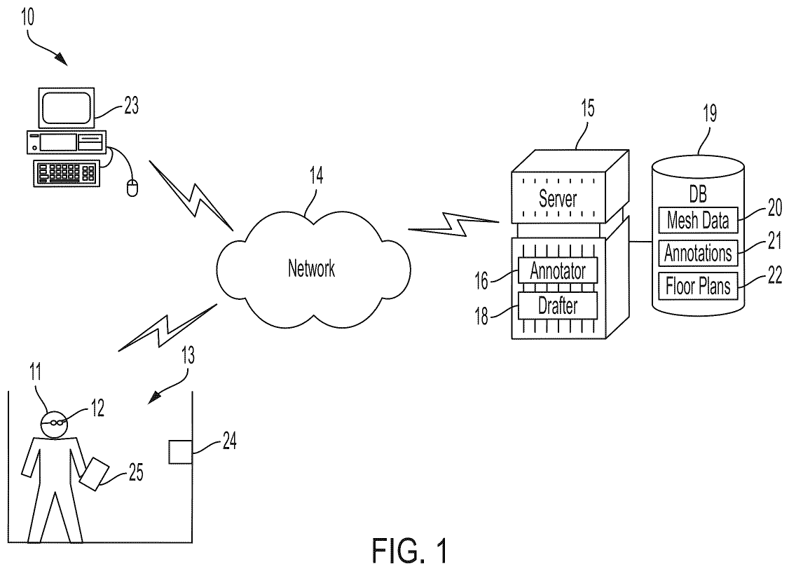

Object capture can include capturing data of an object and annotating models or floorplans of physical environments with the captured data. A floorplan, such as an automatically generated floor plan, can be annotated with object data via labels or markings. In particular, an augmented reality application provides annotation capabilities of the floorplan or model, and supplies the captured, annotated data to backend analytical systems. Augmented reality representations, such as heat maps, can be generated using streams of analytical data from or regarding the objects. FIG. 1 is a block diagram showing a system 10 for capture of physical object data for environment modeling, in accordance with one embodiment. A user 11 puts on an augmented reality headset 12, such as a Microsoft HoloLens 2, to obtain mesh data 20 for a space 13 for which a floorplan is to be generated. The mesh data is transmitted to a server 15 via an internetwork 14. The server 15 is interfaced with a database 19 and includes a processor to execute modules, including a drafter 16 and an annotator 18. The drafter 16 analyzes the mesh data and utilizes an algorithm to determine a position of a floor and walls for generating a data model about an environmental condition and use of a physical environment, such as a floorplan or temporal model of heat, humidity, temperature, and other physical attributes of a space.

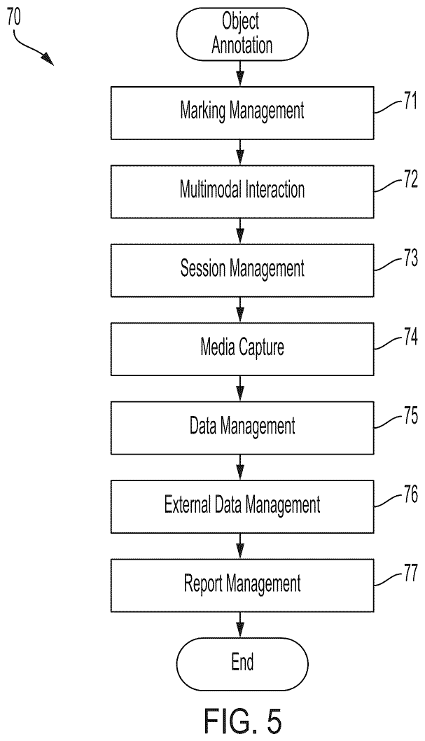

Meanwhile, the annotator 18 receives annotation data from the user 11 and a mobile device regarding an object encountered in the space 13. For example, an object, such as a sensor 24, located in the space 13 is identified by the user 11 using, for example, an application program running on a mobile device 25 or HoloLens 12 operated by the user 11. Examples of other objects include vents, doors, furniture, pipes, wiring, or ducting. Types of annotation data and gathering of the annotation data is further described below with reference to FIG. 5. The annotation data is then used to mark and identify the objects in the floorplan of the space for providing details about the space.

The floorplan can be displayed to the user, such as via a computing device 23 or mobile device 25 over the Internetwork 14. The computing device 23 can include a desktop computer or mobile computing device, such as a cellular phone, laptop, tablet, or other types of mobile computing devices.

In a further embodiment, the augmented head set 12 or mobile device 25 can process the mesh triangle data and annotations to generate a floorplan, which can then be provided to a different device for output. At a minimum, the headset should include a processor and wireless transceiver.

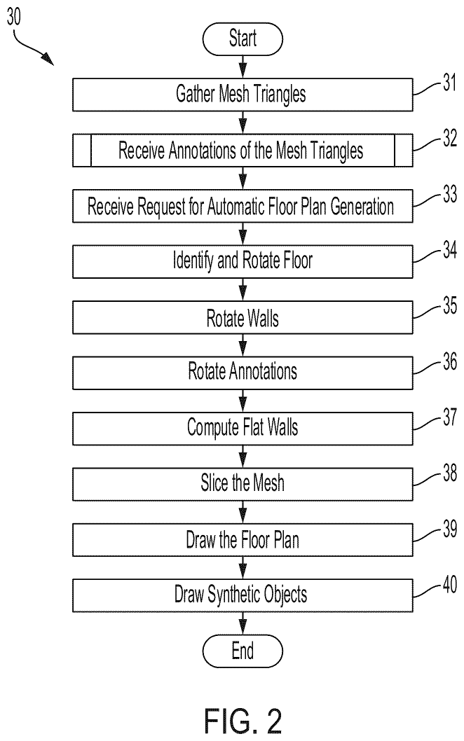

The mesh data utilized for generating the floorplan is obtained by moving around a space, such as by scanning all surfaces, such as walls, doors, floor, ceiling, windows, and objects. The object annotations can be obtained during the scanning and used to supplement the mesh triangle data. FIG. 2 is a flow diagram showing a method 30 for automatic floorplan generation, in accordance with one embodiment. Automatic floorplan generation can commence via an individual user wearing an augmented reality headset that gathers (step 31) mesh triangle data. Specifically, the user puts on the augmented reality headset, such as a Microsoft HoloLens 2, and walks around a space, such as in a building, for which a floorplan is desired. As the user walks, the headset displays mesh triangles over the image or view of the space where the headset detects walls, floors, ceilings, chairs, tables, file cabinets, or other objects within the space. The user continues walking and looking around the space until mesh triangles appear on all of the features that will be important to the floorplan. The mesh triangles viewed can be collected (step 31), transmitted, and stored for processing.

As the user walks around the space, the user can annotate (step 32) the mesh triangles with data to indicate the positions of objects, such as sensors, thermostats, vents, doors, windows, and other important objects. The data can include voice commands and eye gaze data from the user, trace marking, and gesture data, as well as other types of data. For example, when a user is looking at a thermostat, the user can speak “that is a thermostat.” The mesh data for the thermostat, which the user is gazing at, can then be labeled with a thermostat marker. The marker can be an annotation of an aspect of a physical environment for the purpose of assisting more complete and correct model generation and maintenance, and can be in the form of an augmented reality shape, label, symbol, series of lines, or other type of representation of an object or location that the user wants to mark to provide additional information for generation of the model for the space, such as a floorplan. The mobile computing device, including HoloLens, can annotate the mesh data or the annotations can be performed via a server.

Similarly, markers can be added to the mesh data using trace marking, for representation on a display. For example, trace marking utilizes linked trace markers, such as short straight lines, displayed over or along an object, such as pipes, wires, doors, windows, vents, or other objects. A voice command from the user can also be used to identify the series of trace markers, such as “that's a pipe.” Object annotation is further described below with respect to FIG. 5.

When sufficient mesh triangles and objects have been gathered, the user requests the automatic generation of a floorplan. The request is received (step 33), such as by a server, for processing. An algorithm can be used to discover a position (step 34) of a floor in the space using the mesh triangle orientation and dominant surface normal directions of the mesh triangles, as determined by k-means clustering in spherical coordinates. Subsequently, the floor of the mesh is rotated (step 34) to be precisely horizontal. The algorithm can also discover the dominant directions of the walls, if any, using another application of k-means clustering in spherical coordinates. The dominant walls are rotated (step 35) to align with Euclidian coordinates. The object annotations are also rotated (step 36) based on the above rotation transformations of the walls and floor, and are recorded and applied to positions of the objects, so they retain their relationship to the mesh.

If a drafting-style floorplan is desired, flat walls can be computed (step 37). Specifically, the walls can be recognized via an algorithm that applies a modified DBScan algorithm to the mesh triangles to find wall segments, discards wall segments that do not match a wall pattern, and replaces the mesh triangles, in each remaining wall segment, with rectangular blocks. If walls are not necessary to include in the floorplan, computing the walls can be skipped.

The mesh triangles can be sliced (step 38) to produce a set of line segments. In particular, the algorithm can determine an approximate altitude of a ceiling of the space from a histogram of triangle altitudes. A set of altitudes (y values) are chosen in the range from the floor to the ceiling. For example, this distance can be divided into n equal layers, for an integer n. At each altitude, a plane is constructed parallel to the floor at that altitude. The intersection of that plane is computed with the triangle mesh, producing a set of line segments.

Subsequently, the floorplan is drawn (step 39) by setting the y values of all line segments equal to 0, resulting in line segments in two dimensions. Specifically, in any given slice, all of the segments will have the same y value and that y value is the altitude of the slice. All the resulting line segments from all slices are drawn to form a single two-dimensional illustration, which is the floorplan. Finally, the synthetic objects are drawn (step 40). The y values of all synthetic objects are set equal to 0 and drawn onto the floorplan. Once generated, the floorplans can be provided to the user or a third party via a link, an attachment, or web access.

The resulting floorplan is automatically aligned with the horizontal and vertical axes and can show walls, chairs, tables, file cabinets, and other furniture. If desired, the user can annotate the positions of sensors, thermostats, vents, doors, windows, and other objects for display in the floorplan as well, as described in detail below with respect to FIG. 5. A first style of floorplan can resemble a pen-and-ink diagram that shows features at different distances from the floor. A second style of floorplan can resemble a drafting diagram that removes clutter by recognizing walls in a 3D space before projection to 2D. Any user can generate the floorplans as long as an augmented reality headset and access to the floorplan generation algorithms are available. Automated floorplan generation is further discussed in detail in U.S. patent application Ser. No. 18/297,506, to Bier et al., which is hereby incorporated by reference in its entirety.

Further, data can be collected from specific types of objects, such as thermostats or other types of sensors, that have been marked in the space to generate an augmented reality representation. For example, temperature data can be collected from one or more thermostats in a space and used to generate an augmented reality display with temperature values or colors used to represent temperature over the model or floorplan of the space.

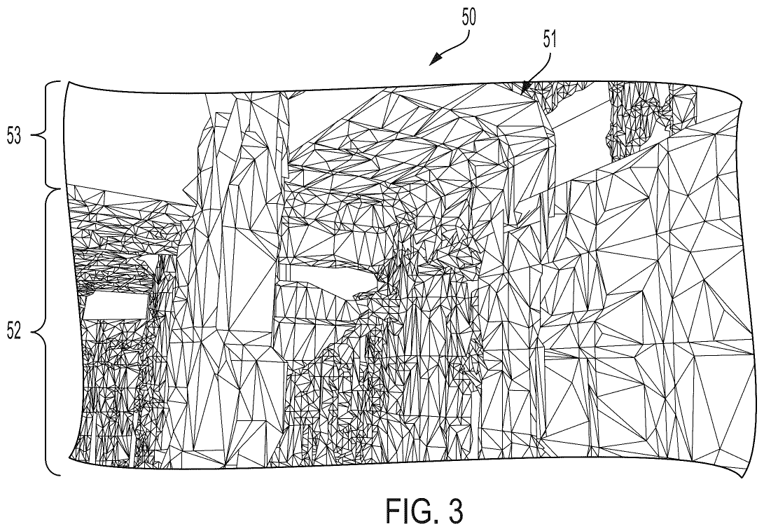

When collecting the mesh data for generating a floorplan, the mesh triangles can be displayed to determine whether enough data has been collected to sufficiently and accurately generate the floorplan. Augmented reality headsets, such as the HoloLens 2, come with hardware and software that constructs 3D triangles that represent the surrounding environment as mesh triangle data. These triangles can be displayed to the user as the user walks around in a space and looks in different directions. FIG. 3 is a block diagram showing, by way of example, a space 50 for which mesh triangles 51 are gathered via an augmented reality headset. As viewed from a user's perspective, the mesh triangles 51 can be overlaid on the user's view of a space, such as a building interior. The headset has already gathered many triangles 51 on the walls 52, but there are still regions of the walls and ceiling 53 where we see gaps that will be filled in as the user walks closer to those regions and looks at them from different points of view. When the gaps have been filled in, the mesh triangle data can be analyzed.

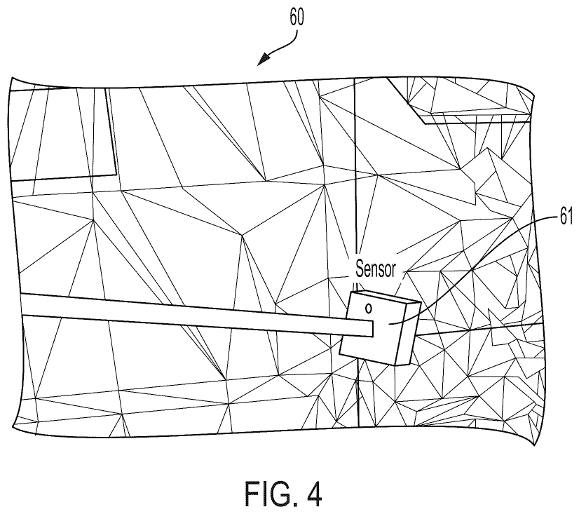

After gathering the mesh triangle data, the user can annotate objects in the space by indicating positions of important objects in the building interior, such as thermostats and sensors. The annotation can occur via eye gaze direction, trace marking, and gesture, along with voice command. For example, using eye gaze, the user looks at an object, such as a sensor, and gives some voice commands that tell the system: 1. The type of the object (e.g., a sensor) 2. The position of the object (the eye gaze point) and 3. Any additional information (e.g., the type of sensor) and then tells the system to add a synthetic object at that position. FIG. 4 is a block diagram showing, by way of example, a portion of a space 60 with a sensor object 61. The sensor 61 is identified and the identification data, along with a representation of the sensor, can be added to the mesh triangle configuration.

Object capture can include capturing data of an object and annotating models or floorplans of physical environments with the captured data. An example scenario includes a technician responsible for instrumenting a space with devices that collect data to be analyzed externally, including sensor commissioning for HVAC optimizing and predictive maintenance. To achieve object annotation, fast and efficient interactive use of multimodal input features afforded by augmented reality is utilized. FIG. 5 is a flow diagram showing a process 70 for capture of physical object data for environment modeling. Capturing physical object data, including object annotation, can be performed sequentially or in different orders. Marking management (step 71) is performed to provide augmented reality annotation of objects, including different devices and predefined features, such as sensors, vents, doors, windows, pipes, and wires. Other predefined features are possible. Specifically, marking management involves trace marking, which uses a repeated dropping of linked trace markers on or along objects, and QR code tracking.

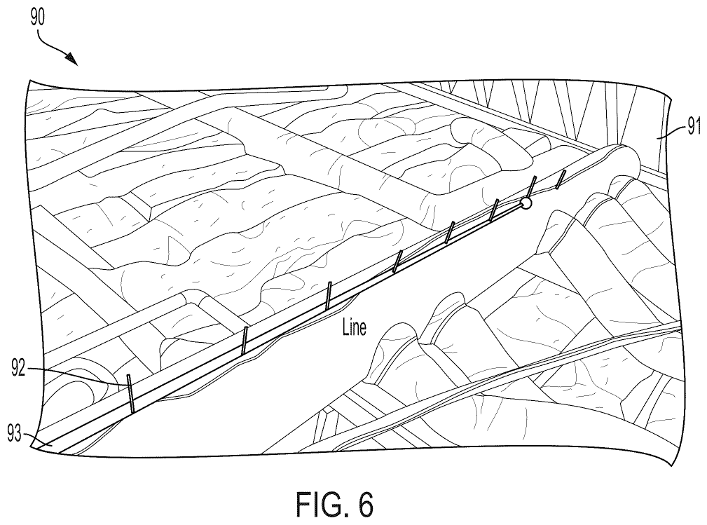

The trace markers can be represented as short, straight lines that extend from a surface of an object outward. FIG. 6 is an image 90 showing, by way of example, trace marking used on an object. The image shows a space, such as an attic, with HVAC ducting 91. Trace markers 92 are dropped along an outer surface of a top side of the HVAC ducting with a main trace line 93 placed along a length of the HVAC ducting. The trace markers 92 are represented as a series of sort lines extending outward from the main trace line 93 along the top side of the HVAC ducting. The trace markers can be placed using voice commands.

For QR code tracking, a QR code can be associated with one or more objects within the space and read by a QR scanner, such as implemented on a mobile computing device. Each QR code is associated with a particular object, such as a sensor, and provides location information about that object. QR code commissioning and tracking is further described in detail with respect to U.S. patent application Ser. No. ______, titled “System and Method for Rapid Sensor Commissioning,” to Bier, and filed on Aug. 31, 2023, which is hereby incorporated by reference in its entirety.

Further, as part of marking management, augmented reality viewing of normal vectors in the special mapping mesh is used to guide object placement, including probe lines in and around objects of interest. Examples of utility probe lines include marking along level sections of walls, columns, and pipes, and marking tops of surfaces, such as liquid storage tanks. Placing and utilizing probe lines are further discussed below in detail with respect to FIGS. 6-8.

Multimodal interactions (step 72) can also be used to help identify and mark objects. For instance, one or more of voice, gaze pointing, and gesture can be used to mark an object for later identification. In one example, a user is using a pair of HoloLens glasses and focuses her gaze on an object, such as a thermostat. Also, the user says “this is a thermostat.” Based on the voice command, a marker or label can be generated for the object, which is identified at the object at which the user is gazing at, at the time of the voice identification of thermostat. At a minimum, any grammatical construction, or fragment of a construction that may be auto-completed, that has been encoded into the commissioning system in the form of keywords, grammar, or other indexing of domain relevant annotations to be recognized by the system can be used and recognized as a voice command. In a different embodiment, a user can point at the thermostat, while speaking the voice command “this is a thermostat.” A label of thermostat is assigned to the object that the user is pointing. The pointing gesture or other movements and gestures by the user can be detected by a motion detector on the HoloLens or mobile computing device, such as a cell phone or tablet, of the user. The label can be displayed over an image or representation of the object in a floorplan or model of the space.

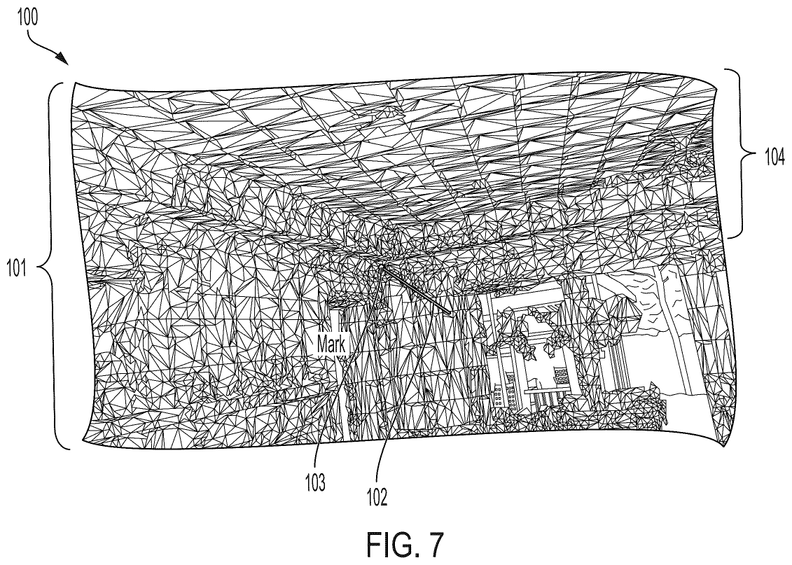

In another example, a user wants to mark a corner of a room to help identify where the ceiling all connecting walls meet for building a more accurate floorplan. FIG. 7 is a screenshot 100 of an image of a space 101 with mesh triangles showing, by way of example, a marker for a corner. A user gazes at the corner and speaks the phrase “mark corner” and a marker 103 is placed at a location at which the user is gazing. A trace line 102 can extend from the location of the marker 103 in a direction of the user's gaze to the location at which the marker is placed. Multimodal interactions can also be used to modify the markers, such as adjusting a size of a marker. As described above in further detail, markers can be labels of objects, as well as tracings of object boundaries or other environmental features, such as corners, edges, and surfaces.

Examples of voice commands can include “assign” for applying a current MAC address to a sensor at which the user is looking, and “bigger/smaller” to incrementally change a height and width. The increments can be identified using configuration data loaded into the system on application start or by user instruction. Specific incremental changes can then be applied in terms of bigger/small or more/less or other such phrasing of increments/decrements, which may be incremented linearly, logarithmically, exponentially, or via other functions. Other examples include “button off/on” to hide or show a button interface from which commands can be selected, “buttons” to reset a hierarchical menu of predefined object names that can be used in place of typing to enter an object name before giving a “name” command, “deeper/shallower” to change depth only of a marker to ensure accurate placement, and “demo on/off” to toggle whether the HoloLens takes a photograph after each mark command or not. In one example, photo taking can be on by default, but must be turned off during demos to enable a live preview mode. Other examples of commands include “fill,” which is used to fit an object marker around an area indicated by three trace markers previously placed by the user around a horizontal or vertical rectangular region, such as on a floor, wall or ceiling. Three markers are used since they are a minimal specification of a rectangular area. Other specifications of a trace area may be appropriate, including an arbitrary number of points with a ‘start’ and ‘stop’ condition to the marking, such as explicitly by receiving start/stop keywords or implicitly by moving on to another command such as “fill.” Other forms of specification may be used to qualify the tracing operation, such as designating a preferred direction use as up, down, or normal to an environmental surface so that two points and a normal line and a preferred direction may specify a 3D area of interest to be traced and annotated.

The trace markers can also be used for line marking by saying “line” instead of “fill.” In one example, a user can stand facing an area to mark and start marking from the top-left corner for walls or farthest left for horizontal surfaces, such as floors and ceilings. The user can proceed marking clockwise to the bottom-right or near right corner of the marking area.

A “flip” voice command can switch explore “mini-lines” to be projected up and down, such as along vertical pipes and columns, or side to side, such as along walls, floors, or surfaces, while a “flip” command sets a data saving mode so that the mesh will be saved along with the marker positions. Other voice commands include “kill minus nine,” which shuts down the application program for mapping and object annotation without saving, “line” briefly shows lines that connect a sequence of trace objects that define a straight or mostly straight object, such as a pipe with each line having a wider end at the end that corresponds with the older trace object, “mark” places a new marker of a current size. One method of setting marker size may be modal, in which the user specifies “small” “medium” or “large” sizes based on configuration data loaded into the system at application start or by user direction. The current size can be whatever marker size was last used or a default marker size or a marker size selected by the user.

Further voice commands can include “mesh off/on” toggles an image of the mesh off or on, “mesh separate/together” saves mesh sections in a separate file or aggregate file, “mesh” shows the current save setting, “more/less” changes increments of any scaleable annotation feature such as length, width, depth, height, distance of separation, and rotation or motion, such as in six degrees or other degrees of freedom, “name” applies a current sensor name (from a “keyboard voice command”) to the sensor that the user is looking at, “next level” changes a triangle per cubic meter value by cycling through coarse, medium, fine, and unlimited values, “level” shows the current level, and “note” provides a mode in which the “mark” command adds a flat rectangle representing a note that can be added to a piece of equipment or furniture with information regarding that equipment or furniture.

Additional commands include “nudge.” When a user is looking near a marker, such as a corner marker that was placed a little bit away from a corner in the space, the “nudge” command is verbalized and the user then looks along the wall towards the corner. The nearest marker to the initial gaze point at the time of the command will follow the gaze point until the mesh normal changes by a threshold amount, such as a normal vector difference of 0.1 meters, so that the marker is placed in the corner.

A “path command” initiates showing of a trace of the path the user wearing an environmental sensing device, such as the HoloLens, takes when annotating the environment. A “photo” command instructs the HoloLens or mobile computing device to take a picture. A marker can be placed at a location of the picture and the picture can be displayed in the floorplan or map, or added as a note. Other commands include “ping,” which briefly shows lines from the HoloLens to all placed markers, “probe, floor, wall” is places the marking probe on the mesh, including probes for aiding the preferred floor and wall orientation, “relocate” applies a correction rotation to all markers about a reference object, which is a point, such as a corner where the “ping” command shows a corner object has moved out of the corner, “remove” deletes a marker that is identified via a gaze focus of the user, “report generates a marker report showing the marking history of a use session of the application program, and “save” saves session data, including the mesh, the marker metadata, and marker geometry files, which can be stored separately or together. If only the marker files are desired, “a partial” command before a “save” command is used. Also, to ensure that mesh files are included, the commands “full” before “save” are used.

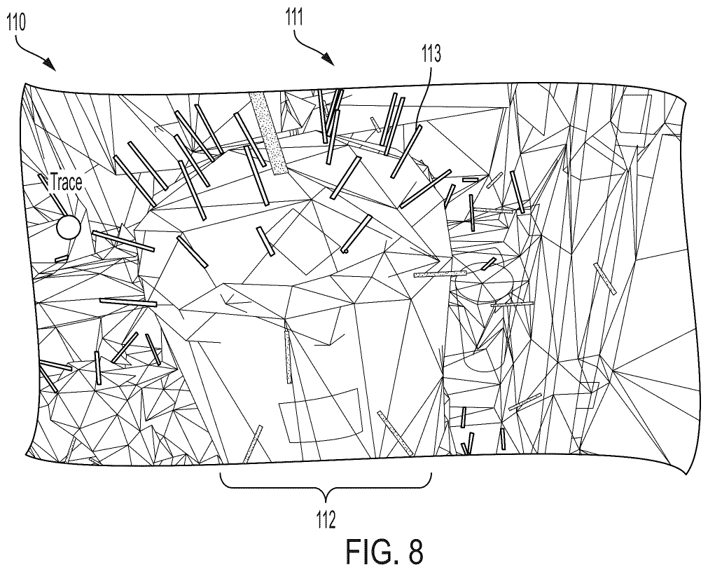

A “session” command starts a new labeling session, which can also initiate display of a keyboard for naming the new labeling session, while a “shower” command temporarily projects a grid of normal lines down from above to indicate the top shapes of objects, such as containers, furniture, or other objects resting of surfaces of the space or surfaces of objects in the space. The normal lines stick out perpendicularly from surfaces in the room as detected by the sensing device, such as the HoloLens, while trace lines follow the direction of points that are applied sequentially by the user. FIG. 8 is a screenshot 110 of an image 111 of a physical space with mesh triangles and normal lines. A water tank 112 is identified in the space via the mesh triangles and further distinguished by normal lines 113 that indicate orientation at the top of a water tank. Specifically, the lines extend outward from a top surface of the water tank and different orientations of the lines can represent different angles of the surface, which may not be flat. Also in the image 111 is a marker, such as a sphere 114, which is displayed to indicate a joint in a pipe or conduit and can also be labeled to distinguish the joint's order in the tracing, such as Trace 0 or Trace 1 or so on.

A “terminate” command stops the application program and a “trace” command adds a trace object using a “mark” command, while in “trace” mode. A sequence of trace objects can be used to define a polyline that represents a long, thin object with ends in it, such as a pipe. Additional commands include a “wider/slimmer” command that changes width only [of what?], a “purge” command that clears all marker positions, a “reset” command that clears all mesh geometry for the space, and a “restart” command clears the reference position, quits the augmented reality application program and restarts the augmented reality application.

Returning to the discussion of FIG. 5, session management (step 72) is utilized to support aggregation of multi-sessions of marking across multiple rooms and hallways, such as in a house or building, by linking objects in a room to a reference marker, and linking reference markers to link markers located between entrances and egresses between rooms. The reference markers and link markers can be placed using voice commands and eye gaze or gesture.

Object annotation also includes media capture (step 74), which automates the capture of audio, images, and video at points of interest in a marking session during which annotations are placed on an object, for later reference and image analysis. The audio, images, and video can be used to provide information about the object, such as an expiration date for a sensor, a maintenance date for an HVAC system, or types of filters need for the HVAC system. Other types of information are also possible. The audio, images, and video can each be displayed, such as via a box or note, in the mesh representation of the space or in the floorplan or model, and be associated with a marker.

Building data management (step 75) accesses web services, including data extracted from a building management system, for acquiring marking labels for easy site-specific text labeling of objects of interest. Building management systems are types of commercial applications designed for keeping track of building properties and operation, such as controlling and monitoring mechanical and electrical plants, including HVAC systems, lighting systems, power systems, fire systems, and security systems. Each building management system is a centralized control system that monitors and manages various aspects of a building's operation, as well as optimizes the building's efficiency, comfort, and security while minimizing energy consumption and operational costs.

External data management (step 76) includes accessing web services hosted by external analytics servers that are used to provide augmented reality representations of modeling data generated from data previously captured for a location, such as a historical representation of sensor data in the form of heat maps, vector flows, and other types of synthetic images related to the models. These are used to guide adjustments to objects in the area, such as sensors and actuators, and re-marking of the environment. Report management (step 77) can document the marking and annotation session performed above.

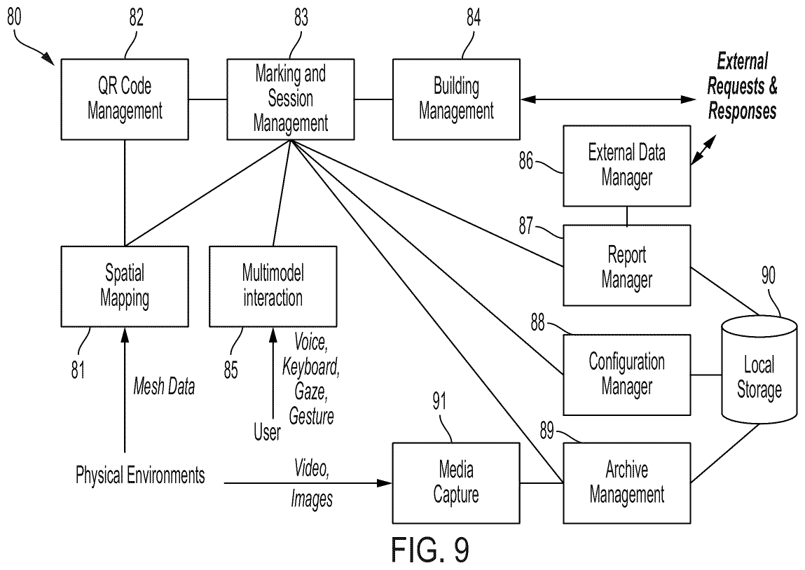

Many functions of the object annotation can be performed at the level of the application program. FIG. 9 is a flow diagram showing, by way of example, interaction 80 of different features of an application for object annotation. A user equipped with one or both of a HoloLens and mobile computing device is located in a physical space for which a model or floorplan is to be generated. Mesh data is collected via the HoloLens to generate a spatial mapping 81 of mesh triangles. The mapping can also include objects identified via QR code management 82, such as described in detail in U.S. patent application Ser. No. ______, titled “System and Method for Rapid Sensor Commissioning,” to Bier, and filed on Aug. 31, 2023, which is hereby incorporated by reference in its entirety, and markers placed in the spatial mapping during a marking session to represent objects in the space using multimodal interactions 85 and building management data 84. Data from the marking session 83 can be provided to a report manager 87 to generate reports for sending to an external data manager 86 and to a configuration manager 88 for building the floorplan or model of the space with the markers. The configuration manager adjusts a size of a marker based on data loaded into the system at application start or by user direction. The data from the marking session 83 also goes to archive management 89 to ensure the data is obtainable from local storage 90. During the scanning of the space by the user, media, such as video, images, and voice can also be captured 91 and stored in local storage 90. The media can be utilized by the configuration manager and report manager in the floorplan or model, as well as reports.

Object data capture, including object annotation, can be used across many industries, such as sensor commissioning, architecture, home modeling, and even trouble shooting for maintenance work. For example, augmented reality visual support can be used to connect onsite workers with a remote system expert. The system expert can help troubleshoot and fix any maintenance problems using object data capture by providing data to the system expert while communicating with the onsite worker.

While the invention has been particularly shown and described as referenced to the embodiments thereof, those skilled in the art will understand that the foregoing and other changes in form and detail may be made therein without departing from the spirit and scope of the invention.

What is claimed is:

1. A system for capture of physical object data for environment modeling, comprising:
a display of mesh data over an image of a physical space for which a floorplan is to be generated;
a mobile computing device configured to perform the following:
receive instructions to mark an object, wherein the instructions comprise one or more of a voice command and eye gaze or gesture; and
annotate the floorplan with a marker based on the instructions by placing the marker at a location at which an object is to be identified;
a server comprising a central processing unit, memory, an input port configured to receive the mesh data and annotations from the mobile computing device, and an output port, wherein the central processing unit is configured to:
generate a floorplan of the space based on the mesh data; and
place the marker in the floorplan.

2. A system according to claim 1, wherein the mobile computing device adjusts a location of the marker in the floorplan based on further instructions.

3. A system according to claim 1, wherein the mobile computing device lays trace lines as the marker, wherein the trace lines each comprise a short line extending from a surface of the object.

4. A system according to claim 1, wherein the mobile computing device generates a reference marker and assigns the reference marker to the object and at least one other object in the space to be linked.

5. A system according to claim 4, wherein the mobile computing device generates a link marker indicating a location between entrances and egresses between rooms in the space, associates the link marker with the reference markers, and associates the link marker with other reference markers in another space associated with a same link marker.

6. A system according to claim 1, wherein the mobile computing device captures media comprising one or more of audio, images, and video at points of interest in the physical space and associates the captured media with the marker.

7. A system according to claim 1, wherein the mesh data can be temporarily removed from the image.

8. A system according to claim 1, wherein the mobile computing device adds a note represented by a box filled with text and associates the notice with the marker.

9. A system according to claim 1, wherein the floor plan is a drafting-style floor plan.

10. A system according to claim 1, wherein the object comprise one or more of a thermostat, sensor, furniture, corner, door, window, pipe, wire, and water tank.

11. A method for capture of physical object data for environment modeling, comprising:
displaying mesh data over an image of a physical space for which a floorplan is to be generated;
receiving instructions to mark an object, wherein the instructions comprise one or more of a voice command and eye gaze or gesture; and
annotating the floorplan with a marker based on the instructions by placing the marker at a location at which an object is to be identified; and
generating a floorplan of the space based on the mesh data; and
placing the marker in the floorplan.

12. A method according to claim 11, further comprising:
adjusting a location of the marker in the floorplan based on further instructions.

13. A method according to claim 11, further comprising:
laying trace lines as the marker, wherein the trace lines each comprise a short line extending from a surface of the object.

14. A method according to claim 11, further comprising:
generating a reference marker; and
assigning the reference marker to the object and at least one other object in the space to be linked.

15. A method according to claim 14, further comprising:
generating a link marker indicating a location between entrances and egresses between rooms in the space;
associating the link marker with the reference markers; and
associating the link marker with other reference markers in another space associated with a same link marker.

16. A method according to claim 11, further comprising:
capturing media comprising one or more of audio, images, and video at points of interest in the physical space; and
associating the captured media with the marker.

17. A method according to claim 11, wherein the mesh data can be temporarily removed from the image.

18. A method according to claim 11, further comprising:
adding a note represented by a box filled with text; and
associating the notice with the marker.

19. A method according to claim 11, wherein the floor plan is a drafting-style floor plan.

20. A method according to claim 11, wherein the object comprise one or more of a thermostat, sensor, furniture, corner, door, window, pipe, wire, and water tank.
